(19) United States
(12) Patent Application Publication
(10) Pub. No.: US 2007/0187804 A1
(43) Pub. Date: Aug. 16, 2007

(54) Monolithic integrated circuit

(76) Inventors: Samir El Rai, Duisburg (DE); Thorsten Sierra, Rheinberg (DE); Ralf Tempel, Duisburg (DE)

Correspondence Address: MCGRATH, GEISSLER, OLDS & RICHARDSON, PLLC, P.O. BOX 1364, FAIRFAX, VA, 22038-1364, US

(21) Appl. No.: 11/584,562

(22) Filed: Oct. 23, 2006

(30) Foreign Application Priority Data
Nov. 4, 2005 (DE) 10 2005 052 637.3

(51) Int. Cl. H01L 23/58

(52) U.S. Cl. 257/644

(57) ABSTRACT

A monolithic integrated circuit is provided that includes at least one transmission line integrated into the circuit. The transmission line includes a series circuit of at least two elementary circuits, wherein each elementary circuit has at least one lumped inductive element (L) and/or at least one lumped capacitive element (C).

This nonprovisional application claims priority under 35 U.S.C. § 119(a) on German Patent Application No. DE 10 2005 052 637.3, which was filed in Germany on Nov. 4, 2005, and which is herein incorporated by reference.

### BACKGROUND OF THE INVENTION

1. Field of the Invention

The invention concerns a monolithic integrated circuit with at least one transmission line integrated into the circuit.

2. Description of the Background Art

Circuits of this type are known, and are used in particular for processing high frequency electromagnetic signals, for example to implement reflection oscillators.

Because an electrical length of technologically important transmission lines is between approximately one eighth of the wavelength and approximately twice the wavelength of the high frequency signal in question, suitable conventional transmission lines, especially in the frequency range around approximately 10 GHz and less, have dimensions that make integration of the transmission lines into conventional monolithic integrated circuits difficult or even impossible.

### SUMMARY OF THE INVENTION

It is therefore an object of the present invention to improve a monolithic integrated circuit of the aforementioned type such that it is possible to integrate a transmission line with a technologically important electrical length into the monolithic integrated circuit, especially also for frequencies in the single-digit gigahertz range.

This object is attained by the invention in a circuit of the aforementioned type in that the transmission line has a series circuit of at least two elementary circuits, wherein each elementary circuit has at least one lumped inductive element and/or at least one lumped capacitive element.

The inventive use of a series circuit with elementary circuits comprised of discrete inductive and/or capacitive elements makes it possible to reduce the geometric dimensions of such a transmission line, in particular its length, so greatly that even transmission lines used in the single-digit gigahertz range with an electrical length in the range of one wavelength can be integrated directly into a monolithic integrated circuit of conventional size.

It has become evident that an embodiment of the inventive transmission line using lumped inductive and/or capacitive elements does not impair wave propagation on the transmission line, provided that the geometric dimensions of an elementary circuit are smaller than approximately one fourth the wavelength of an electromagnetic wave carried by the transmission line.

Advantageously, the lumped inductive and capacitive elements required for implementing an inventive elementary circuit can be manufactured using conventional semiconductor manufacturing processes such that the aforementioned homogeneity condition for the geometric dimensions of the elementary circuit is met.

Investigations carried out by the applicant have shown that the use of lumped inductive and capacitive elements for embodying the transmission line make it possible to reduce its geometric dimensions, in particular its length, by a factor of 50 compared to conventional transmission lines.

On the whole, therefore, the inventive transmission line has a significantly higher area efficiency as compared to conventional transmission lines. The dielectric constant or effective permeability constant of the inventive transmission line, which accordingly is also increased in comparison to conventional transmission lines, also makes it possible to implement transmission lines with a relatively high characteristic impedance of, for example, more than 120 ohms. Thus, when an inventive circuit is used with such a transmission line, it is possible to realize applications with low signal attenuations and low loading of the active components that are connected to the transmission line.

In an embodiment of the present invention, provision is made that the elementary circuit is designed as a four-terminal network. In other words, each elementary circuit has two electric terminals on both an input side and an output side of the elementary circuit, and the inventive series circuit of the elementary circuits is implemented in that the applicable terminals at the output of an elementary circuit are connected to the corresponding terminals of an input of a following elementary circuit.

As an alternative to the inventive embodiment of the elementary circuit as a four-terminal network, it is also possible to provide the elementary circuit with additional terminals, for example in order to make possible more complex circuit arrangements of lumped inductive and/or capacitive elements within the elementary circuit, or to permit the provision of an additional, separate ground conductor, or control line, or the like.

According to another embodiment of the invention, the series circuit only has identically designed elementary circuits, resulting in a homogeneous transmission line, i.e., a transmission line that has the same characteristics over its entire length.

In another embodiment of the present invention, it is also possible for the series circuit to have at least two different types of elementary circuits, by which means it is possible to implement, for example, a transmission line that has varying characteristics over its length.

In another embodiment of the present invention, provision is made that at least one elementary circuit has at least one lumped resistive element. Preferably, the resistive element is an ohmic resistance that can be wired in various ways to the other lumped elements of the elementary circuit in order to achieve different attenuation effects within the elementary circuit. For example, a resistive element of this nature can be used at locations in the transmission line where matching of the characteristic impedance or a predefinable attenuation should be implemented.

In another embodiment of the present invention, provision is made that at least one elementary circuit has a tunable capacitive element and/or a tunable inductive element and/or a tunable resistive element.

The tunability of a capacitive, inductive or even resistive element within an inventive elementary circuit makes it possible to change the parameters that determine the transmission properties of the transmission line even after manufacture of the inventive circuit.

According to another embodiment of the present invention, the tunable capacitive element is designed as a varactor and/or as a configurable capacitor matrix, CDAC (capacitor digital/analog converter).

In particular, a combination of a varactor that permits continuous tunability of the capacitance and a capacitor matrix provides the possibility of very precise setting of the resultant capacitance of the capacitive element.

Accordingly, the tunable inductive element can be designed especially advantageously as a configurable matrix of coils, in which a plurality of inductances or coils can be connected to one another in various combinations, in similar fashion to the CDAC.

According to another variant of the invention, the tunable resistive element can be designed as a configurable resistance matrix and/or have at least one transistor, in particular a field-effect transistor.

In another embodiment of the present invention, provision is made that at least one capacitive element and/or at least one inductive element and/or at least one resistive element is connected in parallel to an input and/or output of the elementary circuit.

In another embodiment of the present invention, provision is made that at least one capacitive element and/or at least one inductive element and/or at least one resistive element is connected in series between an input and an output of the elementary circuit.

Almost any desired combinations of the lumped elements can be implemented by means of the aforementioned inventive circuit configurations, with the result that it is possible to design transmission lines with very different electrical characteristics.

A capacitive element—for example—can be connected in series between an input and an output of the elementary circuit, in order to achieve in this way a high-pass characteristic of the elementary circuit, and thus a transmission line constructed of such elementary circuits. Such a frequency behavior cannot be realized with conventional transmission lines, which normally do not have a non-negligible distributed inductance along the direction of propagation of the electromagnetic waves.

In yet another embodiment of the present invention, provision is made that the elementary circuit has at least one switch, in particular for selective bridging of one or more inductive or capacitive elements and/or for directly connecting different terminals of an input or output of the elementary circuit.

As a result of the inventive provision of at least one switch in the elementary circuit, the configurability of the transmission line is increased still more. In particular, it is possible due to the inventive use of switches in the elementary circuit to design a line termination of the transmission line as an open circuit or as a short circuit, as desired. Moreover, with the use of the switches provided in accordance with the invention, different impedances can be implemented within the relevant elementary circuit, by which means a number of possible termination impedances can be provided, for example.

In another embodiment of the present invention for inductive elements and/or capacitive elements and/or resistive elements can be located in several different, preferably adjacent, metallization levels of the circuit. Particularly in order to achieve high inductance values in the lumped inductive elements, it is advantageous to distribute the conductor configuration that forms the lumped inductive element over multiple adjacent metallization levels.

The parasitic capacitances that arise between different metallization levels of the circuit as a result of its design can also be exploited to implement the lumped capacitive elements in the inventive circuit.

In another embodiment of the inventive circuit, provision is made for the transmission line to be designed as a differential transmission line.

In another aspect of the invention, provision is made in another circuit variant that different regions of the series circuit are each associated with a substrate having different electromagnetic properties, in particular with different dielectric constants and/or permeability constants. The inventive use of different substrate regions with different electromagnetic properties results in a most especially advantageous manner in a further increase in the range of configuration options for the inventive circuit.

In another embodiment of the present invention, provision is made that at least one elementary circuit has at least one transmission line. In particular, transmission lines that are relatively short electrically can if necessary be integrated directly into an elementary circuit in order to take on a predefinable circuit function or to complement the lumped inductive or capacitive elements.

Further advantages, features, and details are evident from the following description, in which various exemplary embodiments of the invention are presented with reference to the drawings. The features mentioned in the claims and in the description may be essential to the invention either individually or in any desired combinations.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 illustrates a schematic representation of a first embodiment of the inventive circuit,

FIG. 2a-FIG. 4a illustrate equivalent circuit diagrams of various embodiments of the inventive elementary circuit, and

FIG. 4b illustrates a simplified representation of a circuit implementation of an elementary circuit whose equivalent circuit diagram is shown in FIG. 4a.

### DETAILED DESCRIPTION

FIG. 1 schematically shows a first embodiment of the inventive monolithic integrated circuit 100. Located in the circuit 100 is a transmission line 200, which according to the invention is implemented in the form of a series circuit having a plurality of elementary circuits 210a, 210b, 210c, etc. The continuation of the series circuit shown in FIG. 1 by additional elementary circuits not shown in FIG. 1 is symbolized by the dots to the right of the elementary circuit 210c.

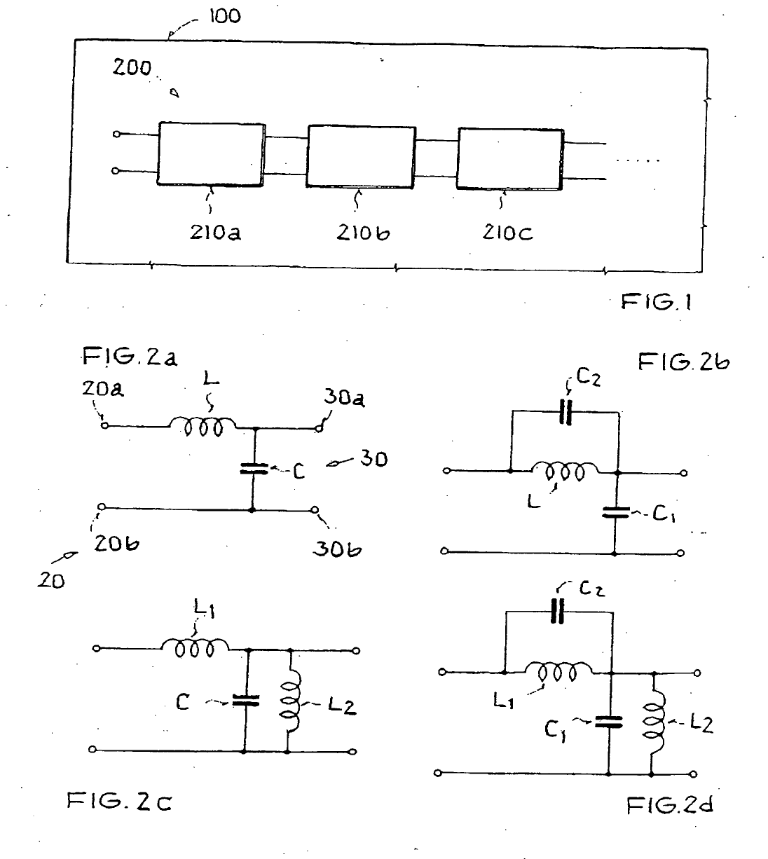

As is evident from FIG. 1, each elementary circuit 210a, 210b, 210c, etc. is designed as a four-terminal network. Corresponding equivalent circuit diagrams are shown in FIGS. 2a through 4a.

FIG. 2a shows a first four-terminal network, which by way of example illustrates a circuit arrangement of an inductive element L and a capacitive element C, which together form one of the aforementioned elementary circuits 210a, 210b, 210c, etc. The four-terminal network depicted in FIG. 2a has an input 20, which has two terminals 20a, 20b, and an output 30, with which the terminals 30a, 30b are associated.

Unlike conventional transmission lines, which, because of parasitic or inherent inductive and capacitive effects exhibit a corresponding distributed inductance or distributed capacitance, each elementary circuit 210a, 210b, 210c, etc. of the inventive circuit 100 (FIG. 1) is equipped with lumped inductive or capacitive elements L, C. In this way, it is possible to realize or simulate far larger distributed inductances or distributed capacitances in the same area than is possible in conventional transmission lines on account of the aforementioned parasitic effects.

Consequently, the transmission line 200 of the inventive circuit 100 can also be produced with, for example, characteristic impedances that are higher than the values known from conventional lines, such as, e.g., 50 ohms or 120 ohms.

When the inventive transmission line 200 (FIG. 1) is equipped with elementary circuits 210a, 210b, 210c, etc. configured as shown in FIG. 2a, the low-pass characteristic already known from conventional transmission lines results, which can be attributed primarily to the series inductance L (FIG. 2a).

In other words, an inventive transmission line 200 designed in this way exhibits essentially the same transmission and frequency characteristics as a conventional transmission line. In contrast, however, the capacitive or inductive contribution effected by the lumped capacitive element C and the lumped inductive element L is significantly higher than a distributed capacitance or distributed inductance such as can be achieved in a conventional transmission line of the same geometric size. As a result, the inventive transmission line 200 has significantly smaller geometric dimensions overall than conventional transmission lines. In this way, it is especially advantageously also possible to realize technologically interesting electrical lengths of approximately ⅛wavelength to approximately twice the wavelength, even when high frequency signals from approximately 1 GHz to about 10 GHz are to be processed with the inventive transmission line 200.

According to investigations carried out by the applicant, the inventive use of lumped capacitances C and lumped inductances L to design the elementary circuits 210a, 210b, 210c, etc. has the effect of reducing the size of the transmission line 200 by a factor of 50 compared to conventional transmission lines. This means that, in order to achieve the same electrical length as in a conventional transmission line, the inventive transmission line 200 (FIG. 1) can have a geometric length reduced by the factor of 50.

The invention thus makes it possible for the first time to integrate even transmission lines intended for the processing of high frequency signals in the single-digit gigahertz range with an electrical length in the range of one wavelength into monolithic integrated circuits 100 (FIG. 1).

Moreover, as a result of the inventive use of lumped inductive or capacitive elements L, C, it is possible to design transmission lines that have entirely novel characteristics.

For example, in a transmission line whose elementary circuits 210a, 210b, 210c, etc. are configured as shown in the equivalent circuit diagram in FIG. 2b, it is possible to achieve, through suitable choice of the capacitance value for the lumped capacitance C2, a high-pass characteristic of the transmission line, which is impossible in conventional transmission lines having a low-pass characteristic.

FIGS. 2c and 2d indicate additional possible circuit configurations for the lumped inductive and capacitive elements L1, L2, C, C1, C2, which may be used to define an inventive elementary circuit 210a, 210b, 210c, etc.

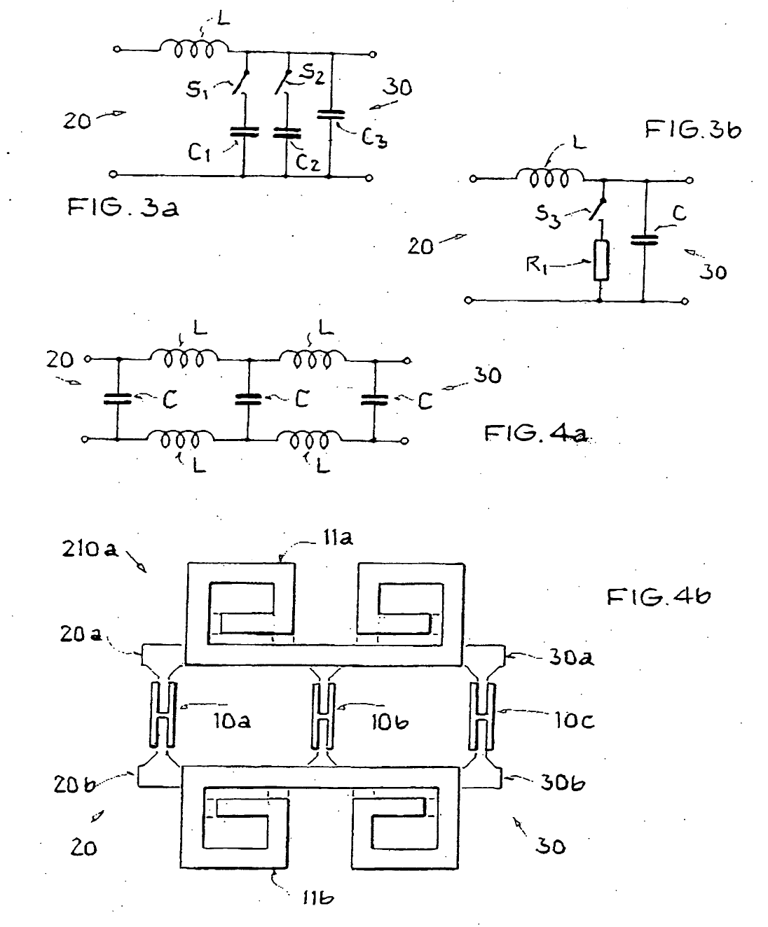

In an especially advantageous embodiment of the present invention, it is additionally possible to provide switches within an elementary circuit. A suitable equivalent circuit diagram is depicted by way of example in FIG. 3a. The four-terminal network shown in FIG. 3a has a lumped inductive element L embodied as a series inductance, and a plurality of lumped capacitive elements C1, C2, C3 arranged in parallel to one another.

As is evident from FIG. 3a, the capacitive elements C1 or C2 can each be connected in parallel to the hard-wired capacitive element C3 by means of the switches S1 or S2, so that a resultant capacitance of the circuit arrangement depicted in FIG. 3a is selectable by appropriately driving the switches S1, S2.

In addition, such a configuration also makes it possible to match the electrical characteristics of the applicable elementary circuit, and hence the inventive transmission line 200 as a whole, even during operation of the inventive monolithic integrated circuit 100 (FIG. 1), by appropriately driving the switches S1, S2.

In place of a lumped capacitive element with a predefined, fixed capacitance value, it is also possible to use a varactor (not shown) in an inventive elementary circuit, producing an even finer tunability of a resultant capacitance.

In similar fashion to the capacitor matrix that can be configured by means of the switches S1, S2, shown in FIG. 3a, a plurality of lumped inductive elements can also be connected in a comparable matrix, so that corresponding tuning of the resultant inductance is possible.

The provision of a resistive element, e.g. such as an ohmic resistance, is likewise possible according to the invention, and is shown in the equivalent circuit diagram of FIG. 3b. As is evident from FIG. 3b, the resistive element R1 can be connected in parallel to the lumped capacitive element C by means of the switch S3, if desired.

In FIG. 4a, another equivalent circuit diagram is depicted that indicates a possible circuit arrangement of lumped inductive elements L and lumped capacitive elements C within an inventive elementary circuit 210a, 210b, 210c, etc. The corresponding circuit implementation in different, stacked metallization levels of the integrated circuit 100 (FIG. 1) is shown in FIG. 4b.

As is evident from FIG. 4b, the lumped inductive elements L shown in FIG. 4a are implemented in the form of spiral coils 11a, 11b, while the lumped capacitive elements labeled with reference character C in FIG. 4a are implemented in the form of the conductor configurations labeled in FIG. 4b with the reference characters 10a, 10b, 10c; these conductor configurations may be MIM (metal insulator metal) capacitors, for example.

The spiral coils 11a, 11b here are integrated primarily in a first metallization level of the monolithic integrated circuit 100 (FIG. 1), while the other electrical conductors, which simultaneously form the terminals 20a, 20b, 30a, 30b of the input 20 or output 30 of the four-terminal network are embodied in a different metallization level, in the present case one located below the first metallization level.

Elementary circuits 210a of the type depicted in FIGS. 4a and 4b are advantageously used for implementing a differential transmission line 200.

Speaking very generally, it is possible to design asymmetric as well as differential transmission lines 200 using the principle underlying the invention. The applicable arrangement of the lumped inductive or capacitive elements L, C should be chosen appropriately for this purpose.

In another very advantageous embodiment of the present invention, a lumped resistive element has at least one transistor, preferably a field-effect transistor. By appropriately driving a gate electrode of the field-effect transistor in this context, an ohmic resistance measured between the drain electrode and source electrode of the field-effect transistor can be influenced in a manner that is known per se, and, for example, an elementary circuit 210a with controllable attenuation may be produced.

In another, very advantageous embodiment of the inventive circuit 100, provision is made that different regions of the series circuit are each associated with a substrate having different electromagnetic properties, in particular with different dielectric constants and/or permeability constants. Through the appropriate choice of these parameters, a further increase in the configurability of the inventive circuit 100 is provided, since the particular values of the dielectric constants and/or permeability constants influence the characteristics of the lumped inductive or capacitive elements L, C, among other effects.

On the whole the inventive embodiment of the transmission line 200 with a plurality of lumped inductive and capacitive elements L, C makes possible transmission lines of especially small construction, as well as the implementation of resultant characteristic impedances or propagation constants that cannot be achieved with conventional transmission lines. As a result, it is possible to implement monolithic integrated circuits 100 that use far less space while simultaneously permitting lower signal attenuations and smaller loads on active components.

All of the aforementioned advantages can be realized by using the inventive principle in differential transmission lines as well as in asymmetric transmission lines.

Preferred applications for the inventive monolithic integrated circuit 100 with the novel transmission line 200 are high frequency oscillators, especially including transit-time or reflection oscillators with delay lines that have a positive and/or negative group delay.

In addition, the inventive monolithic integrated circuit 100 can advantageously be used for constructing wideband, low-noise amplifiers. It is also possible to construct wideband matching networks using the inventive circuit 100. On the whole, it is also easily possible to provide multiple inventive transmission lines 200 within a monolithic integrated circuit 100.

Another advantage of using the inventive circuit 100 is in that the transmission line 200 provides the option, with a suitable configuration of the underlying elementary circuits 210a, 210b, 210c, etc. (FIG. 1), of setting the relative bandwidth of the transmission line 200 and its insertion loss separately from one another, which is impossible in conventional transmission lines.

It is most particularly advantageous that the lumped inductive and capacitive elements L, C needed for constructing an inventive elementary circuit 210a, 210b, 210c, etc., can be produced using conventional semiconductor manufacturing processes.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

1. A monolithic integrated circuit comprising:
at least one transmission line integrated into the circuit, wherein the transmission line has a series circuit formed of at least two elementary circuits, wherein each elementary circuit has at least one lumped inductive element (L) and/or at least one lumped capacitive element (C).

2. The circuit according to claim 1, wherein the elementary circuit is a four-terminal network.

3. The circuit according to claim 1, wherein the series circuit only has identically designed elementary circuits.

4. The circuit according to claim 1, wherein the series circuit has at least two different types of elementary circuits.

5. The circuit according to claim 1, wherein at least one elementary circuit has at least one lumped resistive element.

6. The circuit according to claim 1, wherein at least one elementary circuit has a tunable capacitive element and/or a tunable inductive element and/or a tunable resistive element.

7. The circuit according to claim 6, wherein the tunable capacitive element is a varactor and/or a configurable capacitor matrix, CDAC.

8. The circuit according to claim 6, wherein the tunable inductive element is a configurable matrix of coils, LDAC.

9. The circuit according to claim 6, wherein the tunable resistive element is a configurable resistance matrix and/or has at least one transistor.

10. The circuit according to claim 1, wherein at least one capacitive element and/or at least one inductive element and/or at least one resistive element is connected in parallel to an input and/or output of the elementary circuit.

11. The circuit according to claim 1, wherein at least one capacitive element and/or at least one inductive element and/or at least one resistive element is connected in series between an input and an output of the elementary circuit.

12. The circuit according to claim 1, wherein the elementary circuit has at least one switch for selective bridging of one or more inductive and/or capacitive elements and/or for directly connecting different terminals of an input or output of the elementary circuit.

13. The circuit according to one claim 1, wherein inductive elements and/or capacitive elements and/or resistive elements are located in several different, preferably adjacent, metallization levels of the circuit.

14. The circuit according to claim 1, wherein the transmission line is a differential transmission line.

15. The circuit according to claim 1, wherein different regions of the series circuit are each associated with a substrate having different electrical properties, in particular with different dielectric constants and/or permeability constants.

16. The circuit according to claim 1, wherein at least one elementary circuit has at least one transmission line.
